(19) United States
(12) Patent Application Publication
(10) Pub. No.: US 2016/0150649 A1
(43) Pub. Date: May 26, 2016

(54) INTEGRATED PASSIVE MODULE, SEMICONDUCTOR DEVICE AND MANUFACTURING METHOD THEREOF

(71) Applicant: Hsien-Ping PENG, Tainan City (TW)

(72) Inventor: Hsien-Ping PENG, Tainan City (TW)

(21) Appl. No.: 14/952,571

(22) Filed: Nov. 25, 2015

(30) Foreign Application Priority Data
Nov. 25, 2014 (TW) 103140762

(51) Int. Cl. H05K 1/18; H05K 3/30; H05K 3/46; H01L 23/00; H05K 1/03

(52) U.S. Cl. CPC H05K 1/182; H01L 24/81; H05K 1/0306; H05K 3/4644; H05K 3/30; H01L 2924/19011; H05K 2201/10015; H05K 2201/10022; H05K 2201/1003; H05K 2203/025

(57) ABSTRACT

An integrated passive module comprises a ceramic substrate, a planar layer and a thin film laminate. At least one first passive component is embedded in ceramic substrate. The planar layer is disposed on the ceramic substrate. The thin film laminate comprises at least one second passive component and disposed on the planar layer. The thin film laminate is electrically connected to the first passive component. This disclosure also discloses a semiconductor device comprising an integrated passive module and at least one active component. The at least one active component is electrically connected to the first passive component and the second passive component.

### CROSS REFERENCE TO RELATED APPLICATIONS

This Non-provisional application claims priority under 35 U.S.C. §119(a) on Patent Application No(s). 103140762 filed in Taiwan, Republic of China on Nov. 25, 2014, the entire contents of which are hereby incorporated by reference.

### BACKGROUND

1. Technical Field

The invention relates to an integrated passive module, a semiconductor device and manufacturing method thereof.

2. Related Art

Recently, consumer electronics (including mobile phone, notebook computer, digital camera, video game console and wearable computer) become popular and digital home appliances have developed and grown. Thus, demands on passive components increase. Because of numerous demands and high profit, manufacturers of passive component in the world make an effort to satisfy these electronic products: compact, high speed and functionality. Thus, conventional discrete passive components or array passive components gradually change to embed an inductor, a capacitor or other passive component in the substrate to improve functionality. Moreover, it is also applied with 3D packaging technique for further integration.

As the market trend and demand, developing packaging technology needs to satisfy requirements of IC packages and requirements of passive components and optoelectronic components. Thus, it is necessary to develop packaging technology of SiP (System in Package). For example, stacked and 3D package both are classified into SiP. SiP is a packaging process which integrates all systematic functions for IC product by stacking or connecting to at least one different function on a substrate.

Currently, SiP also develops to integrate active and passive components in package by embedding all active and passive component in packaging substrate. Most current chip-type passive components are manufactured by conventional thick film printing process which prints slurry material of passive component on the substrate and then sintering at high temperature. In early stages, this process caused dimensional deviation of line (low precision of line), thickness unevenness and composition unevenness of the slurry, pattern shifting or other problems due to screen tension, screen resolution, slurry mixing or other factors. These problems cause the product yield and product characteristic precision to unfit for requirements of component miniaturization and component precision. Currently, benefiting from advancing apparatus and screen process, printing technique has improved resolution from 100 μm to 40 μm so as to realize embedding component. But it is still difficult or impossible to mass-produce below 40 μm.

### SUMMARY

An integrated passive module comprises a ceramic substrate, a planar layer and a thin film laminate. At least one first passive component is embedded in ceramic substrate. The planar layer is disposed on the ceramic substrate. The thin film laminate comprises at least one second passive component and disposed on the planar layer. The thin film laminate is electrically connected to the first passive component.

In one embodiment, the first passive component includes capacitor, or inductor or varistor.

In one embodiment, the capacitance of the capacitor is smaller than or equal to 100 nF, and the inductance of the inductor is greater than or equal to 1 nH.

In one embodiment, the ceramic substrate further comprises a plurality of electric connection portions, the electric connection portions are exposed from the outer surface of the ceramic substrate, and some electric connection portions are electrically connected to the first passive component.

In one embodiment, the second passive component is disposed on the planar layer.

In one embodiment, the planar layer has a conduction pattern, and the conduction pattern is electrically connected to the first passive component and the second passive component.

In one embodiment, the second passive component includes a capacitor, an inductor or a resistor.

In one embodiment, the capacitance of the capacitor is smaller than or equal to 20 pF, and the inductance of the inductor is smaller than or equal to 50 nH.

In one embodiment, the material of the planar layer includes Polyimide,

Benzocyclobutene, or solder mask.

A semiconductor device comprises an integrated passive module and at least one active component. The integrated passive module comprises a ceramic substrate, a planar layer and a thin film laminate. At least one first passive component is embedded in ceramic substrate. The planar layer is disposed on the ceramic substrate. The thin film laminate is disposed on the planar layer and electrically connected to the first passive component. The thin film laminate comprises at least one second passive component. The at least one active component is electrically connected to the first passive component and the second passive component.

In one embodiment, the active component is disposed on one side of the thin film laminate facing away from the ceramic substrate.

In one embodiment, the semiconductor device further comprises a circuit layout layer disposed between the thin film laminate and the active component. The active component is electrically connected to the first passive component through the circuit layout layer and the thin film laminate.

A method for manufacturing semiconductor device comprises: providing a ceramic substrate in which at least one first passive component is embedded; grinding a surface of the ceramic substrate; forming a planar layer on the surface of the ceramic substrate; and forming a thin film laminate on one side of the planar layer facing away from the ceramic substrate, wherein the thin film laminate comprises at least one second passive component, and the thin film laminate is electrically connected to the first passive component.

In one embodiment, the ceramic substrate is formed by sintering.

In one embodiment, in the grinding, the thickness of the ceramic substrate is reduced by 5-10 μm with grinding.

In one embodiment, the first passive component embedded in the ceramic substrate is formed by thick film process.

In one embodiment, the planar layer is formed by lithography process, and the surface roughness (Ra) of the planar layer is smaller than or equal to 150 Å.

In one embodiment, the method further comprises: disposing an active component on one side of the thin film laminate facing away from the ceramic substrate, wherein the active component is electrically connected to the first passive component and the second passive component.

In one embodiment, the method further comprises: before disposing the active component, forming a circuit layout layer on the side of the thin film laminate facing away from the ceramic substrate, wherein the active component is electrically to the first passive component through the circuit layout layer and the thin film laminate.

In summary, in the integrated passive module, the semiconductor device and the manufacturing method thereof, the first passive component formed by thick film process is embedded in the ceramic substrate, and the second passive component formed by thin film process is disposed on the ceramic substrate. Thus, the density of the passive component increases so as to reduce the overall volume of the integrated passive module or the semiconductor device. It is suitable for SiP package of high performance component.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1 is a schematic diagram of an integrated passive module according to an embodiment;

FIG. 2A is a top view of the package structure of the integrated passive module;

FIG. 2B is a solid schematic diagram of the package structure in FIG. 2A;

FIG. 3A is a schematic diagram of a semiconductor device according to an embodiment;

FIG. 3B is a schematic diagram of another semiconductor device according to an embodiment;

FIG. 3C is a schematic diagram showing an application of the semiconductor device in FIG. 3A;

FIG. 4A is a top view of another semiconductor device according to an embodiment;

FIG. 4B is a side view of the semiconductor device in FIG. 4A;

FIG. 5 is a side view of another semiconductor device according to an embodiment;

FIG. 6 is a flow chart of a method for manufacturing semiconductor device according to an embodiment; and

FIG. 7 is a flow chart of another method for manufacturing semiconductor device according to an embodiment.

### DETAILED DESCRIPTION OF THE INVENTION

The embodiments of the invention will be apparent from the following detailed description, which proceeds with reference to the accompanying drawings, wherein the same references relate to the same elements.

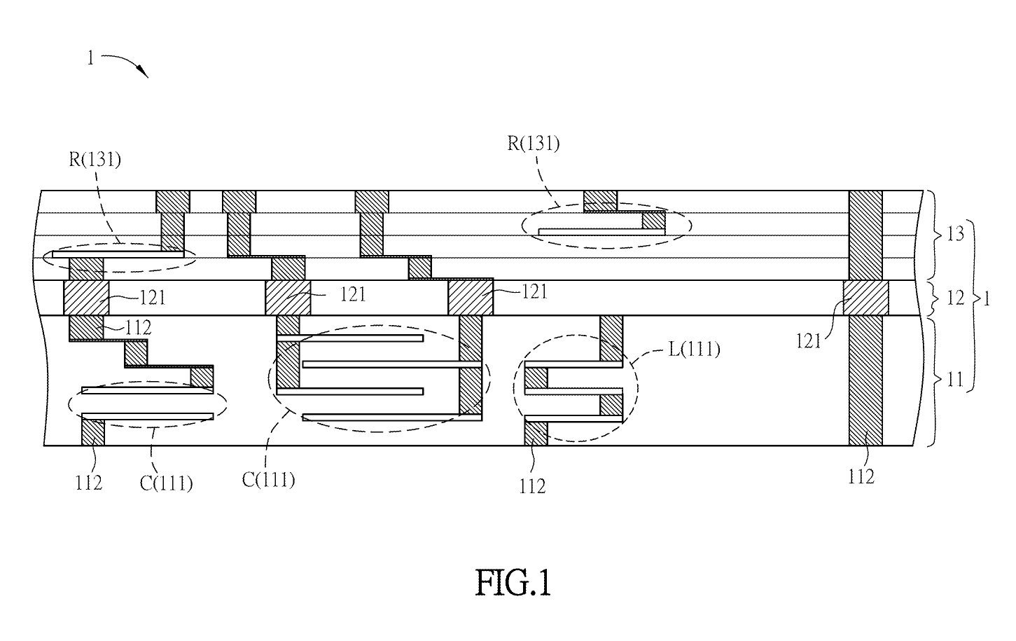

FIG. 1 is a schematic diagram of an integrated passive module according to an embodiment. Referring to FIG. 1, the integrated passive module 1 comprises a ceramic substrate 11, a planar layer 12 and a thin film laminate 13.

The ceramic substrate 11 may be a LTCC (Low-Temperature Cofired Ceramics) substrate or a HTCC (High-Temperature Cofired Ceramics) substrate. The material includes for example but not limited to AlOₓ, AlN_{y}, SiC or BeO. In the embodiment, the ceramic substrate of the integrated passive module 1 is a LTCC substrate for example. The ceramic substrate 11 is formed by co-sintering multiple stacked layers of green tapes in which at least one first passive component 111 is embedded. For example, the process for manufacturing the ceramic substrate 11 includes forming circuit structures on green tapes by laser drilling, microporous grouting, printing precise conductor slurry and/or other processes, and it also includes embedding the first passive component 111 in the circuit structure and then stacking the green tapes and sintering the stacked green tapes at 900° C. Alternatively, in other embodiments, if the ceramic substrate 11 is a HTCC substrate and the metal to be printed is silver-palladium alloy, the sintering temperature ranges between for example 1200-1300° C.

In the embodiment, the first passive component 111 is formed by thick film process (e.g. printing) and embedded in the ceramic substrate 11. The first passive component 111 may be a capacitor, an inductor, or a varistor. For example, the capacitance of the capacitor may be smaller than or equal to 100 nF and greater than 0.5 pF. The inductance of the inductor may be greater than or equal to 1 nH, preferably greater than 50 nH. In the embodiment, two capacitors C and one inductor L are embedded in the ceramic substrate 11 for example.

Moreover, the ceramic substrate 11 further comprises a plurality of electric connection portions 112 exposed from the outer surface (e.g. upper surface or lower surface) of the ceramic substrate 11. At least one part of the electric connection portions 112 is electrically connected to the first passive component 111. Here, the first passive component 111 is electrically connected to components outside the ceramic substrate 11 by the electric connection portion 112.

The planar layer 12 is disposed on the ceramic substrate 11. For example, it is directly disposed on the upper surface of the ceramic substrate 11 or indirectly on the ceramic substrate 11. The material of the planar layer 12 may be or include photoresist or solder mask. The photoresist may be PI (Polyimide) or BCB (Benzocyclobutene) for example. Here, the material of the planar layer 12 is PI for example and formed by lithography process. Such photoresist (PI) is deposited on the surface of the ceramic substrate 11, and the photoresist is exposed, developed, etched and so on by a mask with opening. Then, the developed portion of the photoresist is filled with the conductive material. As a result, the planar layer 12 has a conduction pattern 121 (the portion filled with the conductive material), and the conduction pattern 121 and the first passive component 111 are disposed correspondingly, so the first passive component 111 can be electrically connected to the conduction pattern 121. Moreover, the surface roughness (Ra) of the planar layer 12 is smaller than or equal to 150 Å to help forming the thin film laminate 13 later.

To enhance the bonding strength between the ceramic substrate 11 and the planar layer 12, before forming the planar layer 12, the contact surfaces of the ceramic substrate 11 and the planar layer 12 are ground. Thus, the thickness of the ceramic substrate 11 is reduced by 5-10 μm with grinding to remove surface dust and pollution, and the electric connection portion 112 protruding from the surface of the ceramic substrate 11 is also ground and removed to help forming the planar layer 12 later.

The thin film laminate 13 is a multi-layer composite structure disposed on the planar layer 12 and electrically connected to the first passive component 111. The thin film laminate 13 is disposed on or above the planar layer 12. For example, it is directly disposed on the upper surface of the planar layer 12, or it is indirectly disposed on (above) the planar layer 12. In the embodiment, the thin film laminate 13 is directly formed on the upper surface of the planar layer 12 by the thin film process. The thin film process may include multiple depositing, exposing, developing, etching or other processes. The thin film laminate 13 comprises at least one second passive component 131 disposed on the planar layer 12. The second passive component 131 may include a capacitor, an inductor, a resistor. Preferably, the capacitance of the thin film capacitor is smaller than or equal to 20 pF, and the inductance of the inductor is smaller than or equal to 50 nH. In the embodiment, the second passive components 131 are two resistors R for example. Besides, the conduction pattern 121 of the planar layer 12 is also electrically connected to the second passive component 131. Some first passive components 111 can be respectively electrically to the second passive components 131 through the conduction patterns 121.

Moreover, because the ceramic substrate 11 is thicker than the thin film laminate 13, the first passive component 111 may be a passive component of larger volume, for example a varistor, a high capacitance capacitor or a high inductance inductor, and the second passive component 131 may be a passive component of smaller volume for example a resistor, an inductor or a capacitor. Furthermore, the first passive component 111 and the second passive component 131 can constitute for example but not limited to an accumulator, a high-pass filter, a low-pass filter, a band-pass filter, a common mode filter, or other functional components. As a result, in the embodiment, the integrated passive module 1 with functionality is composed because the thin film laminate 13 is disposed above the ceramic substrate 11, the first passive component 111 is embedded in the ceramic substrate 11 and the thin film laminate 13 has the second passive component 131. In comparison with the conventional circuit board, in the embodiment, because the passive component is embedded in the ceramic substrate 11, the volume of the ceramic substrate 11 is utilized more efficiently in the integrated passive module 1 so as to reduce the overall volume of the integrated passive module 1. Moreover, in the embodiment, high capacitance or high inductance passive component is embedded in the ceramic substrate 11 instead of disposed in the thin film laminate 13. Thus, it may avoid the problem of the serious warpage and incapability of lithography process caused by the residue thermal stress of the insulation material in the thin film layer due to high temperature hardening because it is not necessary to increase layers of thin film to manufacture high capacitance or high inductance passive component like conventional manners.

Moreover, linewidth and spacing of wire in the ceramic substrate 11 may be larger than 40 μm, and linewidth and spacing of wire in the thin film laminate 13 may be larger than 5 μm. If the resolution is between 5 μm and 40 μm, lithography thin film process is preferred.

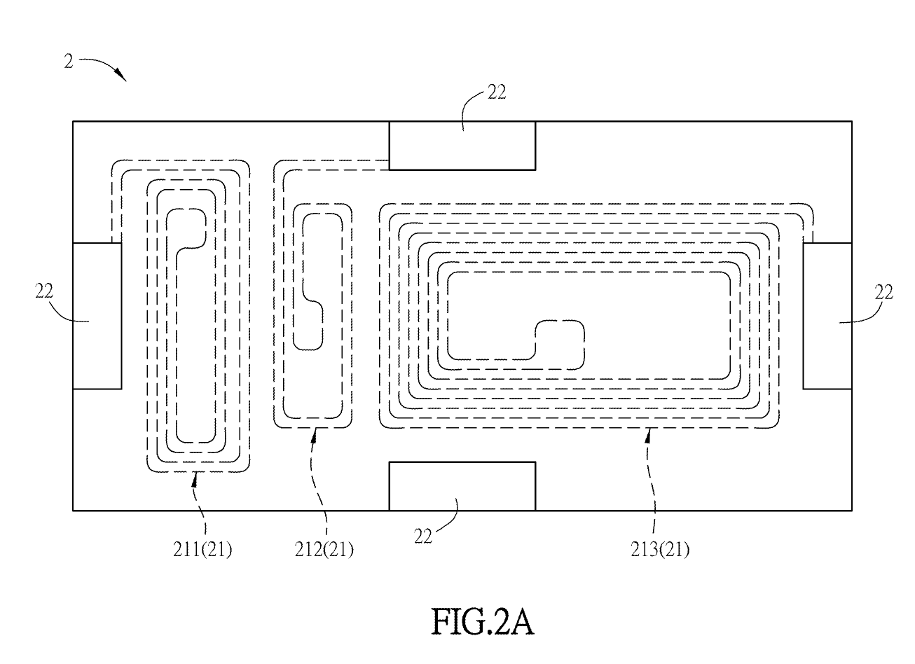

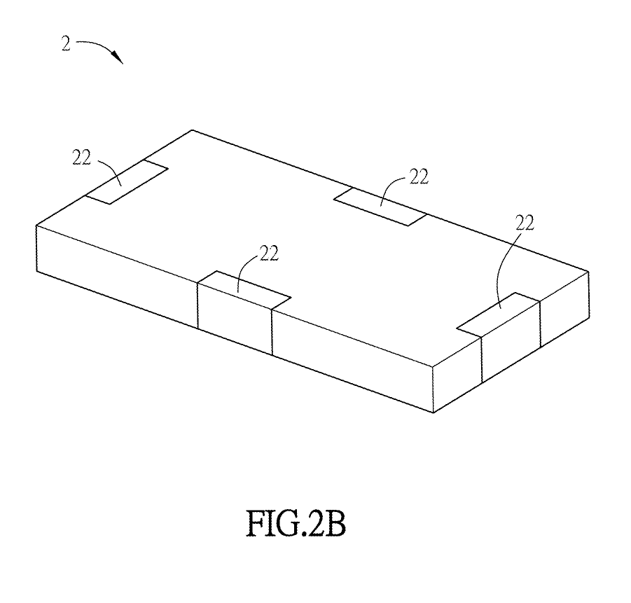

FIG. 2A is a top view of the package structure of the integrated passive module. FIG. 2B is a solid schematic diagram of the package structure in FIG. 2A. Referring to FIG. 2A and FIG. 2B, the package structure 2 is manufactured from the integrated passive module by packaging process. In the embodiment, the package structure 2 of the integrated passive module is a diplexer module for example. A capacitor component (not shown) is embedded in the ceramic substrate and the thin film laminate has three passive components (three coil labeled with dotted line) 21. Four terminal electrodes 22 are located at the outer of the package structure 2, and the passive component 21 is electrically connected to the external component through the terminal electrode 22. Here, the passive component 21 includes for example but not limited to a common port inductor 211, a high frequency port inductor 212 and a low frequency port inductor 213.

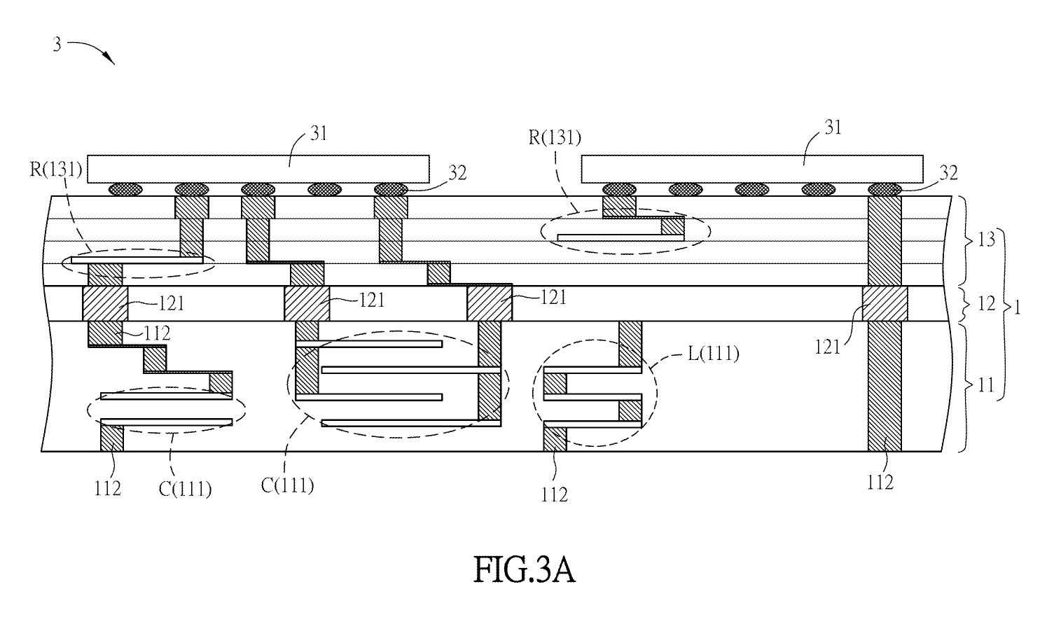

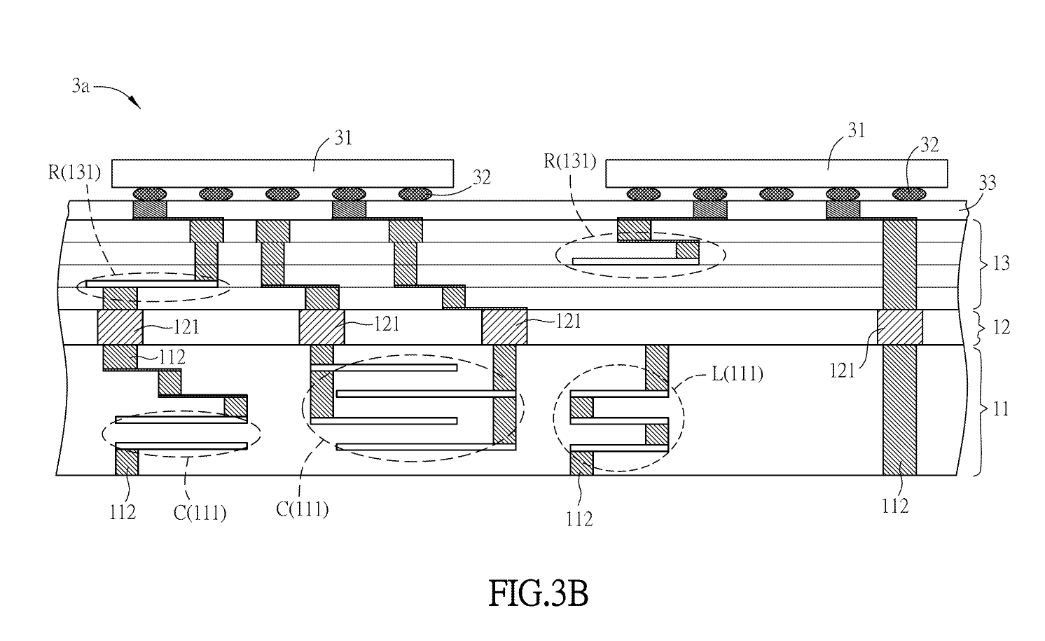

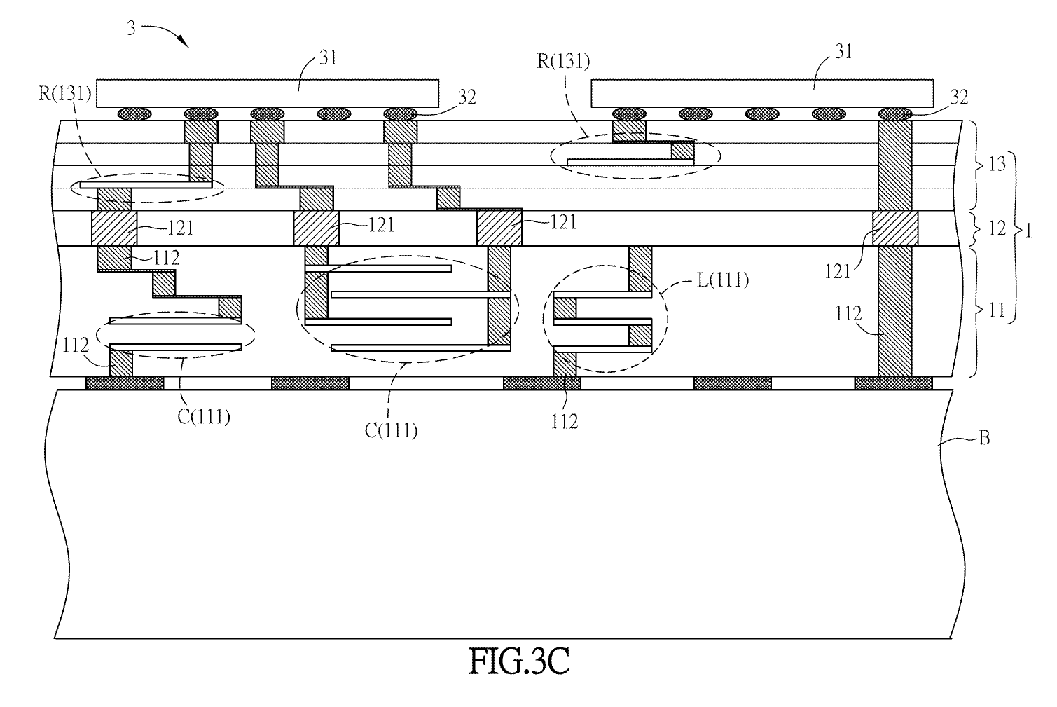

FIG. 3A is a schematic diagram of a semiconductor device according to an embodiment. Referring to FIG. 3A, the semiconductor device 3 comprises an integrated passive module 1 and at least one active component 31. In the embodiment, there are two active components 31 for example. Because the related description of integrated passive module 1 can refer to the previous embodiment, it is not repeated here.

In the embodiment, the active component 31 is disposed at one side of the thin film laminate 13 facing away from the ceramic substrate 11, and electrically connected to the first passive component 111 and the second passive component 131. The active component 31 may be electrically connected to the integrated passive module 1 by for example but not limited to the conductive material (e.g. the tin ball) 32. The active component 31 may be a transistor, a switch, an encoder, a decoder, a power amplifier, or a memory cube, etc. In the embodiment, the semiconductor device 3 may be disposed on the integrated passive module 1 by the active component 31 and electrically connected to the passive component (the first passive component 111 and/or the second passive component 131) of the integrated passive module 1 to compose a complete package chip or circuit board. Because the integrated passive module 1 has the passive component therein, additional passive components may be disposed on the surface of the integrated passive module 1 as little as possible in the semiconductor device 3. The volume of the ceramic substrate 11 is utilized more efficiently so as to reduce the overall volume of the semiconductor device 3. For example, the maximum thickness of the semiconductor device 3 can be reduced to less than 2 mm, even less than 1 mm.

FIG. 3B is a schematic diagram of another semiconductor device according to an embodiment. Referring to FIG. 3B, in the embodiment, the semiconductor device 3a further comprises a circuit layout layer 33 disposed between the thin film laminate 13 and the active component 31. The active component 31 is electrically connected to the first passive component 111 through the circuit layout layer 33 and the thin film laminate 13. For example, the circuit layout layer 33 is formed by multiple mask processes, and it matches the wire of the thin film laminate 13 based on the pin location of the active component 31.

FIG. 3C is a schematic diagram showing an application of the semiconductor device in FIG. 3A. Referring to FIG. 3C, the semiconductor device 3 may be disposed on a circuit board B having conductive lines. Generally, the area of the circuit board B is larger than the area of the ceramic substrate 11. The semiconductor device 3 is electrically connected to the conductive lines on the circuit board B through some electric connection portion 112 on the outer surface of the ceramic substrate 11 to form SiP structure. Moreover, the semiconductor device 3 may be electrically connected to the circuit board B through the package structure of the solder ball (tin ball), bonding pad or QFN (Quad Flat No-lead). In the embodiment, the semiconductor device 3 is applied with a QFN package for example, and it is disposed on the circuit board B by SMT (Surface-mount technology) after applied with solder paste.

Moreover, regarding conventional TSV (through silicon via) in 3D IC structure, an interposer needs to be properly inserted between chips to reserve space for wire bonding or to redistribute chip pins. In most 3D IC structure, one silicon interposer is utilized to redistribute periphery array pads in narrow spacing into the packaged circuit board having surface array pads in wide spacing. Then, the packaged circuit board linking to an active component is installed on a system level circuit board. As a result, the overall thickness of 3D IC structure increases. But in the embodiment, the integrated passive module 1 includes the ceramic substrate 11 where the first passive component 111 is embedded and includes the thin film laminate 13 having the second passive component 131. Namely, the integrated passive module 1 itself is a system level carrier board, so it can replace the packaged circuit board and the system level circuit board in conventional 3D IC to redistribute chip pins and carry the active component. In the embodiment, the integrated passive module 1 may be applied to TSV (through silicon via) 3D IC structure. As a result, the thickness of the overall package structure can be reduced and the density of 3D IC package is enhanced.

Moreover, the diameter of the copper pillar for electrical connection in conventional silicon interposer is below 10 μm, but conventional thick film process or PCB process can not achieve this dimension. In the integrated passive module 1 in the embodiment, the thin film laminate 13 is utilized to complete the necessary wire and copper pillar for electrical connection on the ceramic substratel, so it achieves similar dimension and linewidth to the conventional silicon interposer for enhancing line precision. Furthermore, the coefficient of thermal expansion of the ceramic substrate 11 is 5-7 ppm which is close to that of the active component, so they are stress-matching.

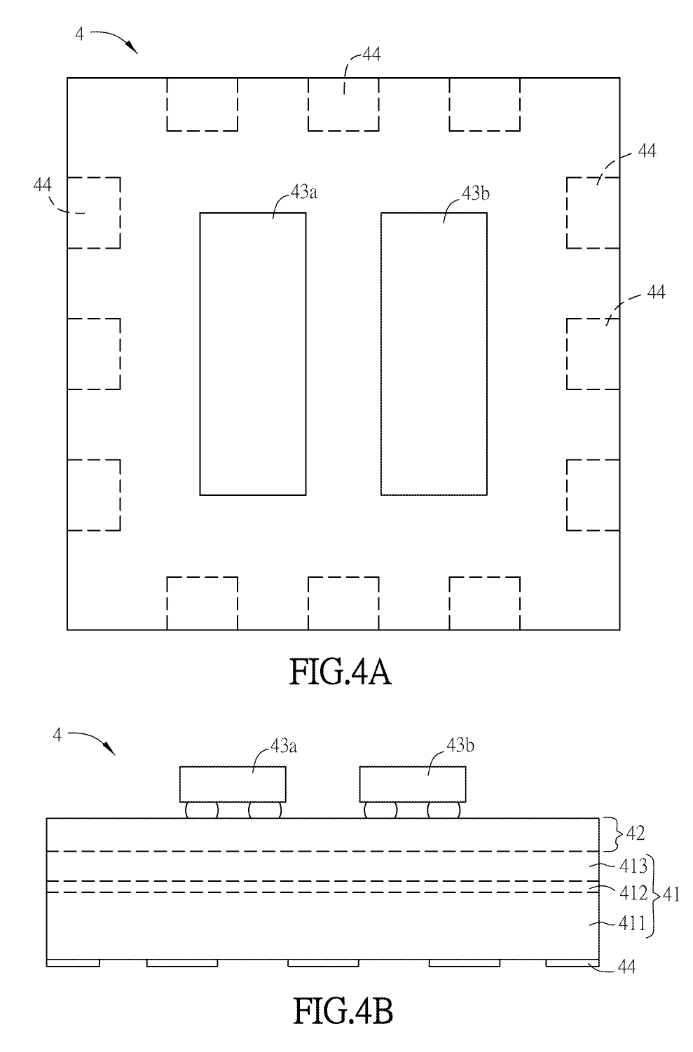

FIG. 4A is a top view of another semiconductor device according to an embodiment. FIG. 4B is a side view of the semiconductor device in FIG. 4A. Referring to FIG. 4A and FIG. 4B, the semiconductor device 4 comprises an integrated passive module 41, a circuit layout layer 42 and two active components (e.g. a decoder 43a and a switch 43b) and a plurality of QFN pins 44. The integrated passive module 41 comprises a ceramic substrate 411, a planar layer 412 and a thin film laminate 413. Because the elements of the semiconductor device 4 and their relationships can refer to the previous embodiments, they are not repeated here.

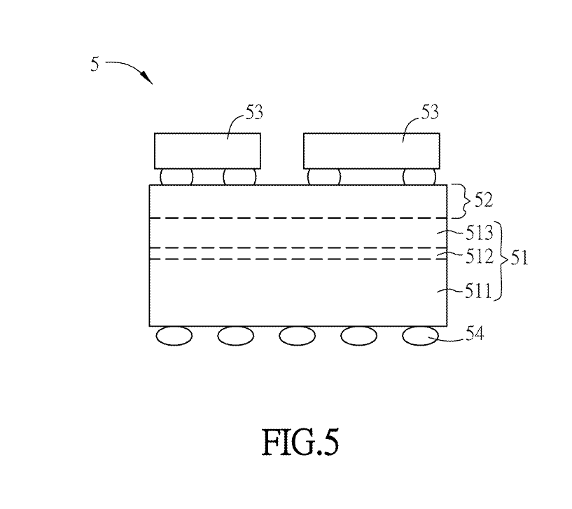

FIG. 5 is a side view of another semiconductor device according to an embodiment. Referring to FIG. 5, in the embodiment, the semiconductor device 5 comprises an integrated passive module 51, a circuit layout layer 52 and two active components 53 (two ICs for example). For example, it is a BGA (Ball Grid Array) package structure, and the semiconductor device 5 also comprises a plurality of tin balls 54. Similarly, the integrated passive module 51 comprises the ceramic substrate 511, the planar layer 512 and the thin film laminate 513. Because their relationships can refer to the previous embodiments, they are not repeated here. Here, if the semiconductor device 5 is a BGA package structure, due to high pin density, the dimension of the integrated passive module 51 of the semiconductor device 5 can be reduced more, even its size is as large as up to the required area for two active components 53.

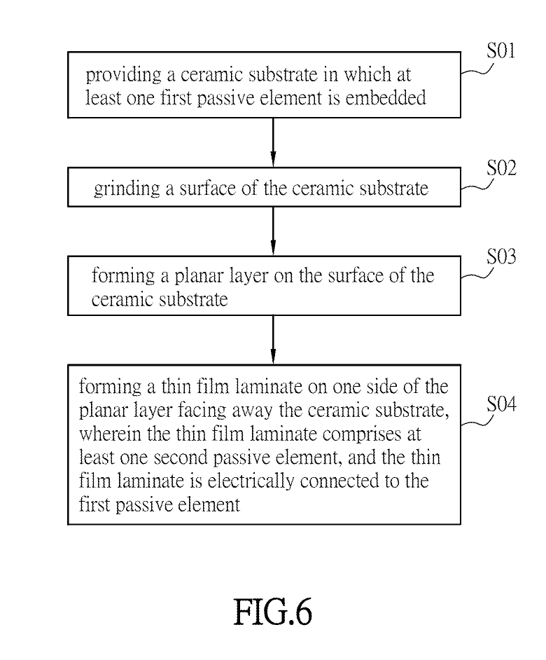

FIG. 6 is a flow chart of a method for manufacturing semiconductor device according to an embodiment. Referring to FIG. 1 and FIG. 6, the method of the embodiment can manufacture the previously mentioned integrated passive module 1. Because the structure and element relationships of the integrated passive module 1 have been described previously, they are not repeated here. The method for manufacturing the integrated passive module 1 comprises: providing a ceramic substrate in which at least one first passive component is embedded (S01); grinding one surface of the ceramic substrate (S02); forming a planar layer on the surface of the ceramic substrate (S03); and forming a thin film laminate at one side of the planar layer facing away from the ceramic substrate, wherein the thin film laminate comprises at least one second passive component and the thin film laminate is electrically connected to the first passive component (S04).

In step S01, the first passive component 111 is formed by thick film process and embedded in the ceramic substrate 11. It is also processed by cosintering. The ceramic substrate 11 is manufacturing by low temperature co-firing or high temperature co-firing.

Then in step S02, the surface of the ceramic substrate 11 is ground, and its thickness is reduced by about 5-10 μm with grinding. Thus, the surface is more planar, and the electric connection portion 112 protruding from the surface of the ceramic substrate 11 or residual Hydrophobic Pollutants after sintering is ground and removed for helping directly disposing the planar layer 12 later.

In step S03, the planar layer 12 is formed by lithography process, and the surface roughness (Ra) of the planar layer 12 is smaller than or equal to 150 Å. Then in step S04, the thin film laminate 13 is formed on the planar layer 12 by thin film process. The thin film laminate 13 is a multi-layer composite structure having the second passive component 131. Therefore, through steps S01 to S04, the previously mentioned integrated passive module 1 is manufactured.

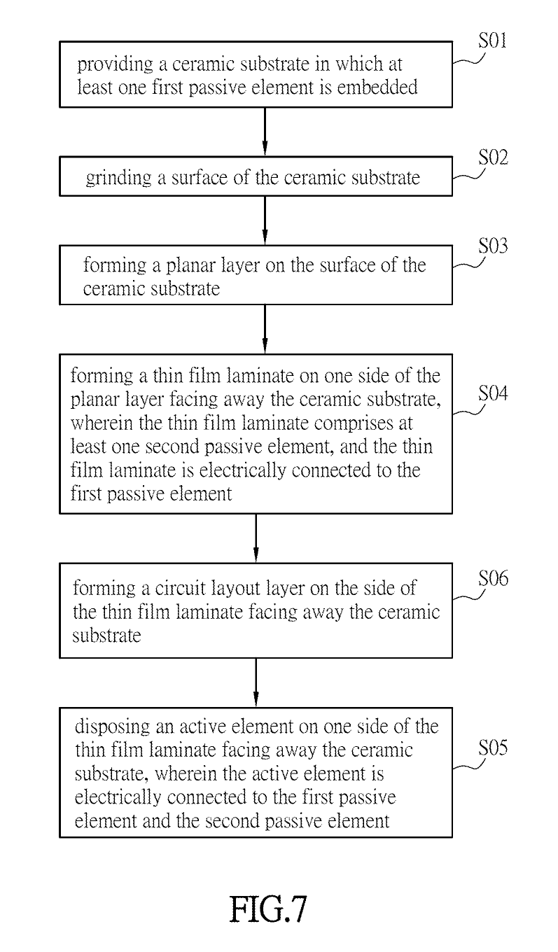

Moreover, the method for manufacturing the integrated passive module 1 may further comprises step S05: disposing an active component 31 at the side of the thin film laminate 13 facing away from the ceramic substrate 11. The active component 31 is electrically connected to the first passive component 111 and the second passive component 131. Referring to FIG. 3A and FIG. 7, FIG. 7 is a flow chart of another method for manufacturing semiconductor device according to an embodiment. In step S05, the active component 31 is electrically connected to the integrated passive module 1 by for example but not limited to the conductive material (e.g. tin ball or QFN) 32. Because the related description of the active component 21 can refer to the previous illustration, it is not repeated here.

Moreover, referring to FIG. 3B and FIG. 7, the method further comprises: before disposing the active component 31, forming a circuit layout layer 33 at the side of the thin film laminate 13 facing away from the ceramic substrate 11. The active component 31 is electrically connected to the first passive component 111 through the circuit layout layer 33 and the thin film laminate 13. Here, the circuit layout layer 33 is formed by mask process, and it is located between the active component 31 and the thin film laminate 13.

In summary, in the integrated passive module, the semiconductor device and the manufacturing method thereof, the first passive component formed by thick film process is embedded in the ceramic substrate, and the second passive component formed by thin film process is disposed on the ceramic substrate. Thus, the density of the passive component increases so as to reduce the overall volume of the integrated passive module or the semiconductor device. It is suitable for SiP package of high performance component.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An integrated passive module, comprising:
a ceramic substrate in which at least one first passive component is embedded;
a planar layer disposed on the ceramic substrate; and
a thin film laminate comprising at least one second passive component and disposed on the planar layer, wherein the thin film laminate is electrically connected to the first passive component.

2. The integrated passive module of claim 1, wherein the first passive component includes a capacitor, an inductor or a varistor.

3. The integrated passive module of claim 2, wherein the capacitance of the capacitor is smaller than or equal to 100 nF, and the inductance of the inductor is greater than or equal to 1 nH.

4. The integrated passive module of claim 1, wherein the ceramic substrate further comprises a plurality of electric connection portions, the electric connection portions are exposed from the outer surface of the ceramic substrate, and some electric connection portions are electrically connected to the first passive component.

5. The integrated passive module of claim 1, wherein the second passive component is disposed on the planar layer.

6. The integrated passive module of claim 1, wherein the planar layer has a conduction pattern, and the conduction pattern is electrically connected to the first passive component and the second passive component.

7. The integrated passive module of claim 1, wherein the second passive component includes a capacitor, an inductor or a resistor.

8. The integrated passive module of claim 7, wherein the capacitance of the capacitor is smaller than or equal to 20 pF, and the inductance of the inductor is smaller than or equal to 50 nH.

9. The integrated passive module of claim 1, wherein the material of the planar layer includes Polyimide, Benzocyclobutene, or solder mask.

10. A semiconductor device, comprising:
an integrated passive module comprising:
a ceramic substrate in which at least one first passive component is embedded;
a planar layer disposed on the ceramic substrate; and
a thin film laminate disposed on the planar layer and electrically connected to the first passive component, wherein the thin film laminate comprises at least one second passive component; and
at least one active component electrically connected to the first passive component and the second passive component.

11. The semiconductor device of claim 10, wherein the active component is disposed on one side of the thin film laminate facing away from the ceramic substrate.

12. The semiconductor device of claim 10, further comprising:
a circuit layout layer disposed between the thin film laminate and the active component, wherein the active component is electrically connected to the first passive component through the circuit layout layer and the thin film laminate.

13. A method for manufacturing semiconductor device, comprising:
providing a ceramic substrate in which at least one first passive component is embedded;
grinding a surface of the ceramic substrate;
forming a planar layer on the surface of the ceramic substrate; and
forming a thin film laminate on one side of the planar layer facing away from the ceramic substrate, wherein the thin film laminate comprises at least one second passive component, and the thin film laminate is electrically connected to the first passive component.

14. The method of claim 13, wherein the ceramic substrate is formed by sintering.

15. The method of claim 13, wherein in the grinding, the thickness of the ceramic substrate is reduced by 5-10 μm with grinding.

16. The method of claim 13, wherein the first passive component embedded in the ceramic substrate is formed by thick film process.

17. The method of claim 13, wherein the planar layer is formed by lithography process, and the surface roughness (Ra) of the planar layer is smaller than or equal to 150 Å.

18. The method of claim 13, further comprising:
disposing an active component on one side of the thin film laminate facing away from the ceramic substrate, wherein the active component is electrically connected to the first passive component and the second passive component.

19. The method of claim 18, further comprising:
before disposing the active component, forming a circuit layout layer on the side of the thin film laminate facing away from the ceramic substrate, wherein the active component is electrically to the first passive component through the circuit layout layer and the thin film laminate.
